(19) United States
(12) Patent Application Publication
(10) Pub. No.: US 2018/0236489 A1
(43) Pub. Date: Aug. 23, 2018

(54) PIEZOELECTRIC SENSOR MANUFACTURING METHOD AND PIEZOELECTRIC SENSOR USING THE SAME

(71) Applicant: BEFS CO., LTD., Seoul (KR)

(72) Inventor: Changhyeok BANG, Seoul (KR)

(21) Appl. No.: 15/897,665

(22) Filed: Feb. 15, 2018

(30) Foreign Application Priority Data
Feb. 17, 2017 (KR) 10-2017-0021755

(51) Int. Cl. B06B 1/06; H01L 41/27; H01L 41/047; H01L 41/08; H01L 41/09; G02B 5/30; G06K 9/00

(52) U.S. Cl. CPC B06B 1/06; H01L 41/27; H01L 41/0475; G06K 9/0002; H01L 41/0973; G02B 5/30; H01L 41/0815

(57) ABSTRACT

The present invention relates to a piezoelectric sensor manufacturing method, and the piezoelectric sensor manufacturing method according to the present invention includes the steps of: forming a mold in the form of a sensor array pattern including a plurality of grooves by etching a semiconductor substrate; injecting and sintering a piezoelectric material in the grooves; forming piezoelectric rods in the form of a sensor array pattern by etching the semiconductor substrate to protrude the piezoelectric material, i.e., etching to protrude a first area at one side of the pattern; forming an insulation layer by filling an insulation material in the semiconductor substrate; flattening the insulation layer until the piezoelectric material is exposed; forming a first electrode on a first surface of the piezoelectric material and the insulation layer; bonding a dummy substrate on the semiconductor substrate on which the first electrode is formed; flattening a second surface of the semiconductor substrate until the piezoelectric material is exposed; forming a second electrode on a second surface of the piezoelectric material; and exposing the first electrode by etching the first area.

### BACKGROUND OF THE INVENTION

### Cross Reference to Related Application

The present application claims the benefit of Korean Patent Application No. 10-2017-0021755 filed in the Korean Intellectual Property Office on Feb. 17, 2017, the entire contents of which are incorporated herein by reference.

### FIELD OF THE INVENTION

The present invention relates to a piezoelectric sensor manufacturing method and a piezoelectric sensor using the same, and more specifically, to a piezoelectric sensor manufacturing method which can easily apply electrodes by exposing a lower electrode and an upper electrode in the same direction, and a piezoelectric sensor manufactured using the same.

### BACKGROUND OF THE RELATED ART

User authentication is a procedure absolutely necessary in all financial transactions, and particularly, as the interest in mobile financing increases recently owing to development of networks and portable terminals, demands on rapid and accurate authentication apparatuses and authentication methods also increase.

Meanwhile, fingerprints of a user are one of authentication media which can meet the demands described above, and many companies and developers continuously develop apparatuses and methods for authenticating a user by utilizing fingerprints of a user.

Recently, in relation to fingerprint recognition apparatuses, studies on the method of grasping the forms of a fingerprint by generating ultrasonic waves, i.e., a so-called ultrasonic method, are actively progressed, getting out of a method of authenticating images of a fingerprint in a conventional optical method.

Particularly, as security of ultrasonic piezoelectric sensors is further strengthened compared with existing optical or capacitive methods, many studies on the sensors are progressed.

If a voltage is applied to a piezoelectric material, the piezoelectric material vibrates as ultrasonic waves are generated, and the ultrasonic piezoelectric sensor senses a fingerprint.

In an existing piezoelectric sensor having two electrodes needed for application of power, one of the electrodes is formed on the top of the piezoelectric sensor, and the other is formed on the bottom of the piezoelectric element. That is, the piezoelectric element includes an upper electrode and a lower electrode.

Conventionally, there are many difficulties in applying voltage as the two electrodes are formed in different direction like this.

### SUMMARY OF THE INVENTION

An object of the present invention is to provide a piezoelectric sensor manufacturing method, which can arrange an upper electrode and a lower electrode in the same direction.

In addition, another object of the present invention is to provide a piezoelectric sensor manufacturing method, which can arrange an upper poling electrode and a lower poling electrode in the same direction.

The piezoelectric sensor manufacturing method according to an embodiment of the present invention may include the steps of: forming a mold in the form of a sensor array pattern including a plurality of grooves by etching a semiconductor substrate; injecting and sintering a piezoelectric material in the grooves; forming piezoelectric rods in the form of a sensor array pattern by etching the semiconductor substrate to protrude the piezoelectric material, i.e., etching to protrude a first area at one side of the pattern; forming an insulation layer by filling an insulation material in the semiconductor substrate; flattening the insulation layer until the piezoelectric material is exposed; forming a first electrode on a first surface of the piezoelectric material and the insulation layer; bonding a dummy substrate on the semiconductor substrate on which the first electrode is formed; flattening a second surface of the semiconductor substrate until the piezoelectric material is exposed; forming a second electrode on a second surface of the piezoelectric material; and exposing the first electrode by etching the first area.

In the piezoelectric sensor manufacturing method according to an embodiment of the present invention, the step of forming piezoelectric rods in the form of a sensor array pattern by etching the semiconductor substrate to protrude the piezoelectric material, i.e., etching to protrude a first area on one side of the pattern, may etch the semiconductor substrate to further protrude a second area and a third area in predetermined areas of the semiconductor substrate, and the step of exposing the first electrode by etching the first area may further etch the second area and the third area.

In the piezoelectric sensor manufacturing method according to an embodiment of the present invention, the step of forming a first electrode may include the steps of: depositing a metal layer on the piezoelectric rods; applying photoresist on the metal layer; removing part of the photoresist by exposing to light according to a mask pattern; etching the metal layer of the part from which the photoresist is removed; and removing remaining photoresist after etching the metal layer.

In the piezoelectric sensor manufacturing method according to an embodiment of the present invention, the step of forming a first electrode may include the step of forming a first poling electrode in the second area and the third area by depositing a metal layer in the second area and the third area.

In the piezoelectric sensor manufacturing method according to an embodiment of the present invention, the first electrode may be connected to the first poling electrode in one piece.

In the piezoelectric sensor manufacturing method according to an embodiment of the present invention, the step of forming a second electrode may include the step of forming a second poling electrode in a predetermined area of a second surface of the insulation layer.

In the piezoelectric sensor manufacturing method according to an embodiment of the present invention, the second electrode may be a metal layer the same as that of the second poling electrode.

The piezoelectric sensor manufacturing method according to an embodiment of the present invention may further include a poling step of activating the piezoelectric material by applying poling voltage to the first electrode and the second electrode.

In the piezoelectric sensor manufacturing method according to an embodiment of the present invention, the second electrode may be formed to cross the first electrode in a perpendicular direction.

In the piezoelectric sensor manufacturing method according to an embodiment of the present invention, the step of forming a second electrode may include the steps of: depositing a metal layer on the piezoelectric rods; applying photoresist on the metal layer; removing part of the photoresist by exposing to light according to a mask pattern; etching the metal layer of the part from which the photoresist is removed; and removing remaining photoresist after etching the metal layer.

In the piezoelectric sensor manufacturing method according to an embodiment of the present invention, the step of forming a mold may include the steps of: forming a pattern for forming a sensor array on a first surface of the semiconductor substrate through a photolithography process; removing the photoresist formed on the semiconductor substrate and depositing an insulation layer; and forming the grooves at regular intervals on the semiconductor substrate by etching the area from which the photoresist is removed.

In the sintering step of the piezoelectric sensor manufacturing method according to an embodiment of the present invention, the piezoelectric material may be sintered at a low temperature for a first period and sintered at a high temperature for a second period.

In the piezoelectric sensor manufacturing method according to an embodiment of the present invention, the low temperature may be 450 to 550° C.

In the piezoelectric sensor manufacturing method according to an embodiment of the present invention, the high temperature may be 1050 to 1300° C.

In addition, the piezoelectric sensor according to an embodiment of the present invention may include: a lower electrode; a piezoelectric material of a pillar shape formed on the lower electrode; an upper electrode arranged to cross the lower electrode formed on the piezoelectric material, wherein an outer portion of the lower substrate may be exposed toward a top without forming the piezoelectric material.

### BRIEF DESCRIPTION OF THE DRAWINGS

FIG. 1 is a flowchart illustrating a piezoelectric sensor manufacturing method according to the present invention.

FIG. 2 is a flowchart illustrating a mold forming step in detail.

FIG. 3 is a perspective view showing a semiconductor substrate in a state of completing up to the etching process.

FIG. 4 is a view showing the piezoelectric material injection step in detail in the step of injecting and sintering a piezoelectric material (step S11).

FIG. 5 is a perspective view showing a state of completing injection of a piezoelectric material.

FIG. 6 is a view showing the semiconductor substrate 10 flattened through a CMP process.

FIG. 7 is a perspective view showing the semiconductor substrate in a state of completing the etching process (step S12).

FIG. 8 is a view showing the semiconductor substrate in a state of applying an insulation layer 23.

FIG. 9 is a view showing a state of cutting off the top portion of the insulation layer 23 through a CMP process.

FIG. 10 is a view showing a first electrode forming step (step S14) in detail.

FIG. 11 is a perspective view showing the semiconductor substrate 10 in a state of completing formation of the first electrode 26.

FIG. 12 is a perspective view showing a state of bonding a dummy substrate 28.

FIG. 13 is a view showing a state of completing the CMP process on the semiconductor substrate 10.

FIG. 14 is a view showing an example of forming a second electrode 29 and second poling electrodes 30a and 30b.

FIG. 15 is a view showing a state of removing a first area 19, a second area 20 and a third area 21.

FIG. 16 is a view showing a method of applying a poling voltage.

FIG. 17 is a view showing a piezoelectric sensor created according to the present invention.

DESCRIPTION OF SYMBOLS

| | |
|---|---|
| 10: semiconductor substrate | 11: photoresist |
| 12: mask pattern | 14: groove |
| 16: insulation film | 17: piezoelectric material |
| 19: first area | 20: second area |
| 21: third area | 22: sensor array pattern |
| 23: insulation layer | 24: metal layer |
| 25: photoresist | 26: first electrode |
| 27: first poling electrode | 28: dummy substrate |
| 30: second electrode | 31: silicon oil |

### DETAILED DESCRIPTION OF THE PREFERRED EMBODIMENT

Details of the objects and technical configuration of the present invention described above and operational effects according thereto will be further clearly understood hereinafter by the detailed description with reference to the accompanying drawings attached in the specification of the present invention. The embodiments according to the present invention will be described in detail with reference to the accompanying drawings.

The embodiments disclosed in this specification should not be interpreted or used to limit the scope of the present invention. It is natural to those skilled in the art that the description including the embodiments of the specification has various applications. Accordingly, the arbitrary embodiments disclosed in the detailed description of the present invention are for illustrative purposes and do not intend to limit the scope of the present invention to the embodiments.

The functional blocks shown in the figures and described below are merely examples of possible implementations. In other implements, other functional blocks may be used without departing from the spirit and scope of the detailed description. In addition, although one or more functional blocks of the present invention are expressed as individual blocks, one or more of the functional blocks may be a combination of various hardware and software configurations executing the same function.

In addition, the expression of ‘including’ a constitutional sensor is an expression of an ‘open type’ which merely refers to existence of a corresponding constitutional sensor, and it should not be construed as precluding additional constitutional sensors.

Furthermore, it will be understood that when a constitutional sensor is referred to as being ‘connected’ or ‘coupled’ to another constitutional sensor, it may be directly connected or coupled to the other constitutional sensor or intervening sensors may be present.

The expressions such as ‘first’ and ‘second’ are expressions used only to distinguish a plurality of configurations and do not limit the sequence or other features of the configurations.

When an element is connected to another element, it includes a case of indirectly connecting the elements with intervention of another element therebetween, as well as a case of directly connecting the elements. In addition, the concept of including a constitutional sensor means further including another constitutional sensor, not excluding another constitutional sensor, as far as an opposed description is not specially specified.

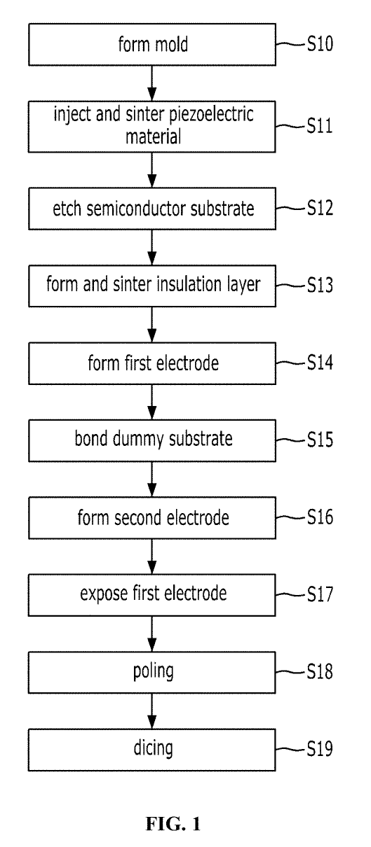

FIG. 1 is a flowchart illustrating a piezoelectric sensor manufacturing method according to the present invention.

Referring to FIG. 1, a piezoelectric sensor manufacturing method includes a mold forming step (step S10), a piezoelectric material injecting and sintering step (step S11), a semiconductor substrate etching step (step S12), an insulation layer forming and flattening step (step S13), a first electrode forming step (step S14), a dummy substrate bonding step (step S15), a second electrode forming step (step S16), a first electrode exposing step (step S17), a poling step (step S18) and a dicing step (step S19).

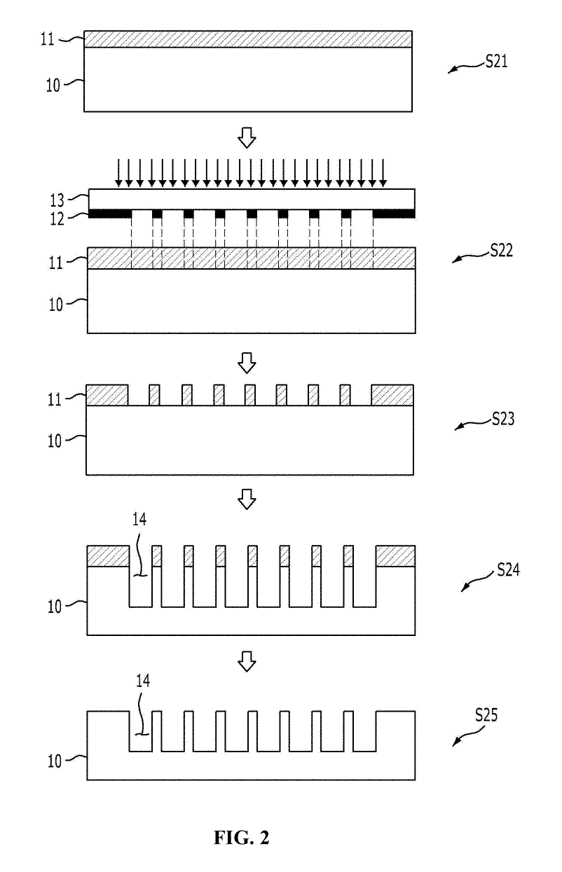

Describing each of the steps in further detail, the mold forming step (step S10) may include the steps shown in FIG. 2.

A mold can be formed using a photolithography process. The photolithography is a technique of copying a desired circuit design by transferring a shadow generated by radiating light on an original plate, i.e., a mask in which the desired circuit design is formed on a glass plate as a metal pattern, on a wafer, and it is the most important process in forming a designed pattern on a wafer in the process of manufacturing a semiconductor. More specifically, the mold forming step includes a coating process of uniformly applying a photoresist composition on the surface of a wafer; a soft baking process of attaching a photoresist film on the surface of the wafer by evaporating solvent from the applied photoresist film; a light exposure process of transferring a pattern of a mask on the photoresist film by exposing the photoresist film to light while repeatedly and sequentially projecting the circuit pattern on the mask to be reduced using a light source such as an ultraviolet ray or the like; a development process of selectively removing the portions having different physical properties, such as difference of solubility according to light sensing of exposure to the light source, using a developer; a hard baking process of further tightly adhering the photoresist film remaining on the wafer after the development process to the wafer; an etching process of etching predetermined portions according to the pattern of the developed photoresist film; and a strip process of removing unnecessary photoresist films after the above processes. A medium is needed to transfer the circuit design of the original plate of the mask to the wafer through the light exposure process since the properties of the materials used for a semiconductor element are not changed although the materials are exposed to light, and the medium is referred to as photoresist (PR). The photoresist refers to a material which can selectively remove a portion exposed to light or a portion not exposed to light in the following development process using the characteristic such as the photoresist receives light of a specific wavelength and its solubility is changed in the developer. Generally, the photoresist selectively removes a portion changed by light using a developer, and if a portion receiving the light is melted well by the developer, it is referred to as positive resist, or otherwise, it is referred to as negative resist.

Referring to FIG. 2, first, photoresist is deposited on a prepared semiconductor substrate 10 (step S21). Although the semiconductor substrate 10 may be a silicon single crystal substrate, it also can be a silicon-on-insulator (SOI) substrate, a germanium (Ge) substrate, a gallium phosphide (GaP) substrate, a gallium arsenide (GaAs) substrate or the like, and it is not specially limited. In addition, a circular silicon wafer can be used as the semiconductor substrate 10. In addition, the photoresist 11 is a photoresist material, and a material having a chemical characteristic changed by radiating light of a predetermined wavelength may be appropriately selected and used, and it is not specially limited. The method of forming the photoresist 11 on the semiconductor substrate 10 may be, for example, a spin coating method, a spray coating method or a dip coating method, and it is not limited thereto. Selectively, a bake referred to as a so-called post applied bake (PAB) may be performed after the photoresist 11 is formed in a method such as spin coating or the like. Some of the solvent in the photoresist 11 is removed through the bake, and the photoresist 11 is stably deposited on the semiconductor substrate 10.

Next, the photoresist is removed according to the pattern through the light exposure and development processes. That is, the photoresist of an area in which the mask pattern 12 does not exist is removed by arranging a glass substrate 13 attached with a mask pattern 12 of a shape desired to manufacture on the semiconductor substrate 10 and exposing the photoresist 11 to light (step S22).

The photoresist is removed through the light exposure and development processes, and the portions not exposed to light remain on the substrate (step S23).

If the photoresist 11 is removed, grooves 14 are formed by etching the semiconductor substrate 10 of the areas from which the photoresist is removed (step S24). The etching process of etching the semiconductor substrate 10 may be divided into dry etching and wet etching. The wet etching is a method of removing part of the semiconductor substrate 10 by generating a chemical reaction with the surface of the semiconductor substrate 10 using a chemical solution. Since the wet etching is generally isotropic etching, it generates an undercut and is difficult to form an accurate pattern. In addition, it is disadvantageous in that the process control is difficult, the etchable line width is limited, and a problem of processing additionally generated etching solution occurs. Accordingly, the dry etching capable of compensating for the disadvantages of the wet etching is used more frequently. The dry etching is a process of forming plasma by applying power after injecting reaction gas into a vacuum chamber, and removing part of the semiconductor substrate 10 by chemically or physically reacting the plasma with the surface of the semiconductor substrate 10. In this embodiment, the dry etching which can easily control the process, perform antisotropic etching and form an accurate pattern may be used. Particularly, deep reactive ion etching (DRIE), which is physical etching included in the dry etching, may be used. The DRIE process generates plasma by dissociating gas using an energy source after injecting reactive gas into a vacuum chamber. The etching is accomplished through sputtering by accelerating ions generated in the plasma in the electric field and colliding the ions on the surface of the semiconductor substrate 10.

If the etching on the semiconductor substrate 10 is completed, formation of a mold is completed by completely removing the remaining photoresist 11 (step S25). At this point, the photoresist 11 can be removed in a chemical method or using the plasma.

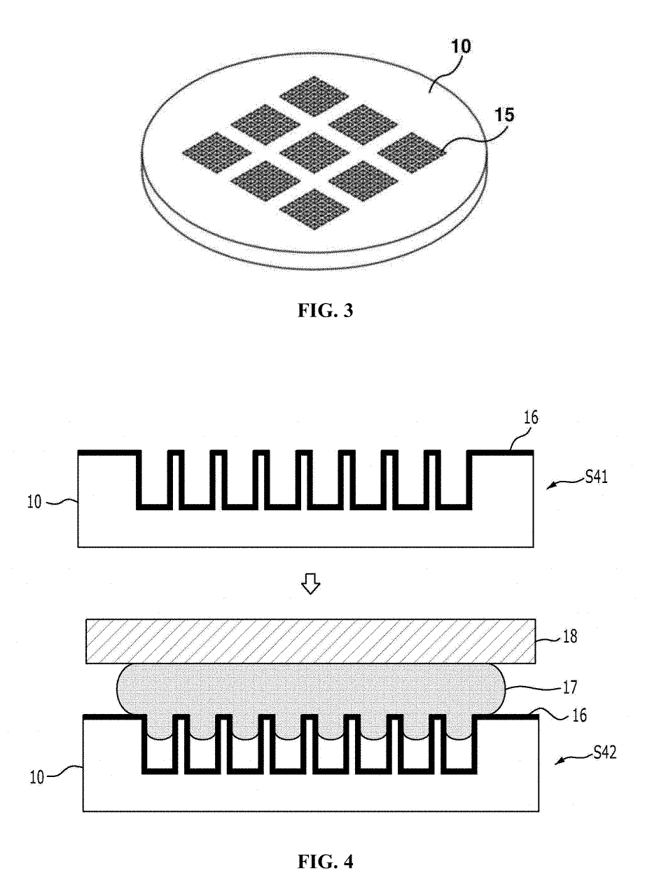

FIG. 3 is a perspective view showing the semiconductor substrate in a state of completing up to the etching process. It may be confirmed that a plurality of sensor array patterns 15 is formed on the semiconductor substrate 10.

If formation of the mold is completed, a piezoelectric material is injected into the holes and sintered (step S11).

FIG. 4 is a view showing the injection step in detail in the step of injecting and sintering a piezoelectric material (step S11).

As shown in FIG. 4, after depositing an insulation film 16 on the semiconductor substrate (step S41), a piezoelectric material 17 may be injected (step S42). Silicon dioxide SiO₂, silicon nitride SiNx, aluminum oxide Al₂O₃ or the like may be used as a material of the insulation film 16. The insulation film 16 may be deposited using Physical Vapor Deposition (PVD) method or Chemical Vapor Deposition (CVD) method as a method of depositing the insulation film. Meanwhile, an example of the PVD method may be a sputtering or e-beam evaporation method.

In addition, lead zirconate titanate (PZT) may be used as the piezoelectric material 17, and the piezoelectric material 18 may be further transparent by adding lanthanum (La). As a method of injecting the piezoelectric material 17, a powder type piezoelectric material is injected as shown in the figure, and the piezoelectric material may be injected by adding pressure from the top using a flat pressing plate 18 not to have a crack in the etched portions. At this point, the piezoelectric material may be injected using hot embossing equipment like HEX 04 of Jenoptik Co.

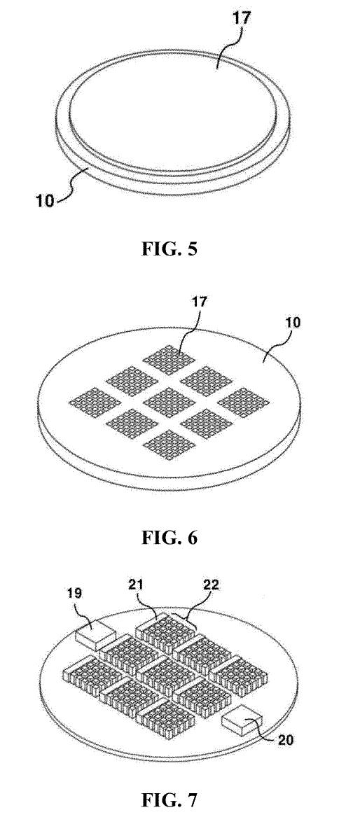

FIG. 5 is a perspective view showing a state completing injection of a piezoelectric material, and it may be confirmed that the piezoelectric material 17 is formed on the semiconductor substrate 10.

If injection of the piezoelectric material is completed, the piezoelectric material is sintered (step S11).

As a method of sintering, the piezoelectric material, e.g., a binder, is burnt out by performing a first sintering at a low temperature, and a second sintering is performed at a high temperature. The first sintering is performed approximately at a temperature of 450 to 550° C. for about one hour, and the second sintering is performed approximately at a temperature of 1200 to 1500° C. for about two hours.

If the sintering process is completed as described above, the semiconductor substrate is flattened through a Chemical Mechanical Polishing (CMP) process and etched to protrude the sensor array pattern (step S12). That is, the cells of the sensor are formed as PZT rods of a pillar shape. Since a portion formed by the piezoelectric material 17 is a piezoelectric rod, the same reference numeral will be used hereinafter for the piezoelectric material and the piezoelectric rod.

FIG. 6 is a view showing the semiconductor substrate 10 flattened through a CMP process. It may be confirmed that the piezoelectric rods 17 are arranged in the form of an array.

Although it is shown in this embodiment that the piezoelectric rod 17 is formed in a rectangular shape, it may be formed in a circular shape and may be implemented in various shapes.

In addition, in the etching process, a mask is formed in a specific area of the semiconductor substrate not to etch a corresponding portion. The dry etching (DRIE) process may be used in the etching process as described above.

FIG. 7 is a perspective view showing the semiconductor substrate in a state of completing the etching process (step S12) in the method as described above.

As shown in FIG. 7, a first area 19, a second area 20 and a third area 21 of the semiconductor substrate 10 are not etched to be protruded. The first area 19 is an area for forming a sensor electrode and may be formed in a predetermined area at one side of the array pattern 22 of the piezoelectric rods 17. The second area 20 and the third area 21 are areas for forming poling electrodes and may be formed in an edge area of the semiconductor substrate. A plurality of sensor array patterns 22 is formed on the semiconductor substrate 10, and each array may operate as one ultrasonic sensor. In addition, a plurality of cells is formed in a pillar shape in one ultrasonic sensor. Formation of a poling electrode and a sensor electrode will be described below. Meanwhile, although only one reference numeral is used to denote the first area 19 for convenience, the same reference numeral may be applied to a plurality of array patterns.

Returning to FIG. 1 again, if the semiconductor etching process (step S12) is completed, an insulation layer is formed by injecting an insulation material 23 in the etched portions of the semiconductor substrate 10, and the semiconductor substrate 10 is flattened (step S13). A CMP process may be used as a method of cutting off the insulation layer. A material capable of attenuating high frequency ultrasonic signals and implementing electrical insulation may be used as the insulation material to optimize the noise and sensitivity of a signal when the piezoelectric sensor operates. For example, an epoxy may be used.

In addition, a flattening process is performed until the piezoelectric rods 17 and the first, second and third areas of the semiconductor substrate are exposed.

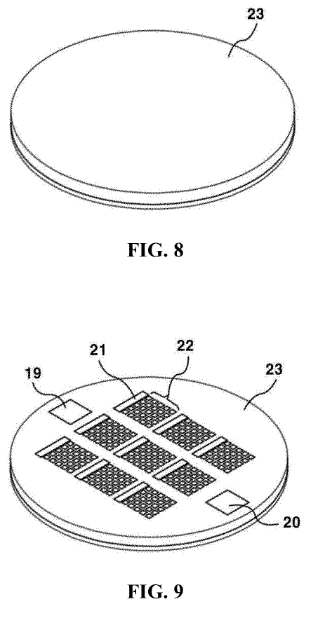

FIG. 8 is a view showing the semiconductor substrate in a state of applying an insulation layer 23, and FIG. 9 is a view showing a state of cutting off the top portion of the insulation layer 23 through a CMP process.

In FIG. 9, since the first area 19, the second area 20 and the third area 21 are initially part of the semiconductor substrate 10, they are formed of a semiconductor material, and the other areas 23 are an insulation layer formed of an insulation material. In addition, the cell array area 22 is formed of a piezoelectric material.

If the insulation layer flattening process (step S13) is completed, a first electrode is formed (step S14).

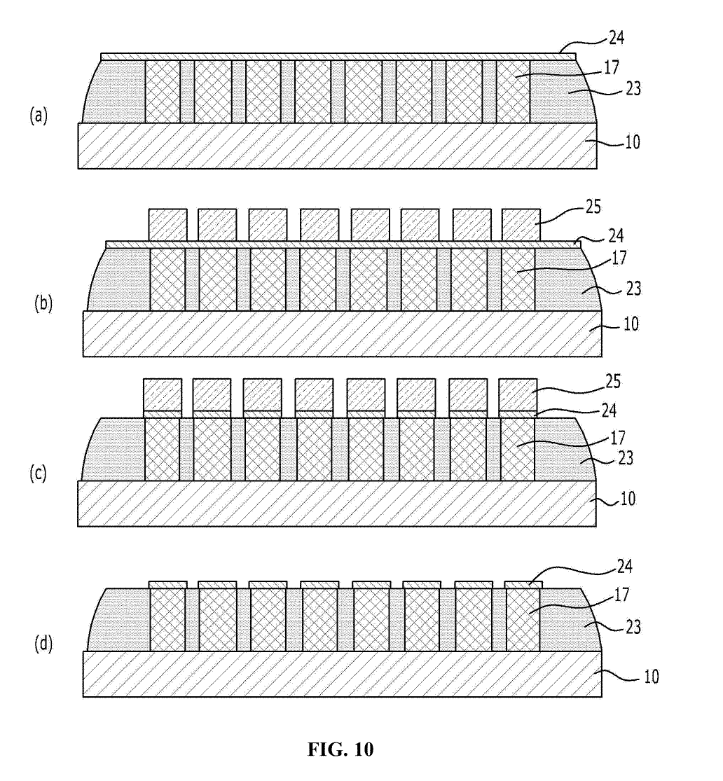

FIG. 10 is a view showing a first electrode forming step (step S14) in detail.

Referring to FIG. 10, first, a metal layer 24 is deposited on the semiconductor substrate 10 (FIG. 10(a)). A sputtering process may be used as the deposition method.

Next, after applying the photoresist 25, part of the photoresist 25 is removed by exposing to light according to a mask pattern (FIG. 10(b)), and the metal layer of the part from which the photoresist 25 is removed is etched (FIG. 10(c)). Formation of the electrode is completed by removing all the photoresist remaining after the metal layer is etched (FIG. 10(d)). The metal layer 24 finally remaining after the etching process becomes the first electrode. At this point, a mask pattern is also formed in the second area 20 and the third area of the semiconductor substrate 10 to form an electrode for poling. The electrode for poling is formed by the metal layer 24 in the same manner as the first electrode.

FIG. 11 is a perspective view showing the semiconductor substrate 10 in a state of completing formation of the first electrode 26.

The first electrode may be a conductive material such as a metal and may be formed through a print process as needed. Observing the first electrode specifically, the first electrode may include any one material selected from a group of copper, aluminum, gold, silver, nickel, tin, zinc and an alloy of these. This is a material which can substitute for existing indium tin oxide (ITO) and may be formed in a cost-effective and simple process. In addition, since it can demonstrate a further superior electrical conductivity, electrical characteristics can be improved. In addition, the first electrode may include metal oxide such as indium zinc oxide, copper oxide, tin oxide, zinc oxide, titanium oxide or the like. In addition, the first electrode may include a nanowire, a photosensitive nanowire film, a carbon nanotube (CNT), graphene, a conductive polymer or a mixture of these. If a nanocomposite such as a nanowire or a carbon nanotube (CNT) is used, the first electrode may be formed in black color and has an advantage of controlling the color and reflectivity while securing electrical conductivity through the control of nano-powder content. Alternatively, the first electrode may include various metals. For example, the electrode may include at least any one metal among chrome (Cr), copper (Cu), aluminum (Al), silver (Ag), molybdenum (Mo), gold (Au), titanium (Ti) and an alloy of these.

Referring to FIG. 11, it may be confirmed that a plurality of first electrode lines 26 is connected to the first poling electrodes 27a and 27b in one piece. Although all the first electrode 26 and the first poling electrodes 27a and 27b are formed by the metal layer 24, different names are assigned according to functions.

Next, a dummy substrate is bonded on the semiconductor substrate 10.

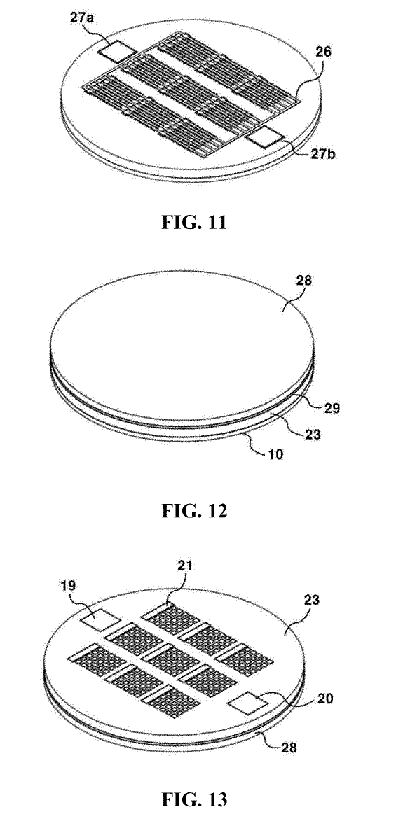

FIG. 12 is a perspective view showing a state of bonding a dummy substrate 28.

After the first electrode is formed, the second electrode should be formed on the opposite side by inverting the semiconductor substrate 10. The dummy substrate 28 is needed for the following process. The dummy substrate 28 may be bonded to the insulation layer 23 using an adhesive. Various adhesive materials such as a thermosetting resin, an optical film, an optical resin and the like may be used as the adhesive.

If the dummy substrate 28 is bonded, the substrates are inverted to face the dummy substrate 28 upward and the semiconductor substrate 10 downward, and the semiconductor substrate 10 is flattened through the CMP process. At this point, the semiconductor substrate 10 is flattened until the piezoelectric material 17 and the insulation layer 23 are exposed.

FIG. 13 is a view showing a state of completing the CMP process on the semiconductor substrate 10. If this process is completed, as shown in the figure, only the insulation layer is formed on the dummy substrate 28, and all the semiconductor substrate, except some areas 19, 20 and 21, is removed and does not remain.

If the CMP process on the semiconductor substrate 10 is completed, a second electrode is formed (step S16). The second electrode may be formed in a method the same as the method of forming the first electrode. That is, as shown in FIG. 10, the second electrode may be formed in a method of depositing a metal layer and patterning and etching the metal layer through a photolithography process. At this point, a second poling electrode may be formed in an edge area of the insulation layer 23.

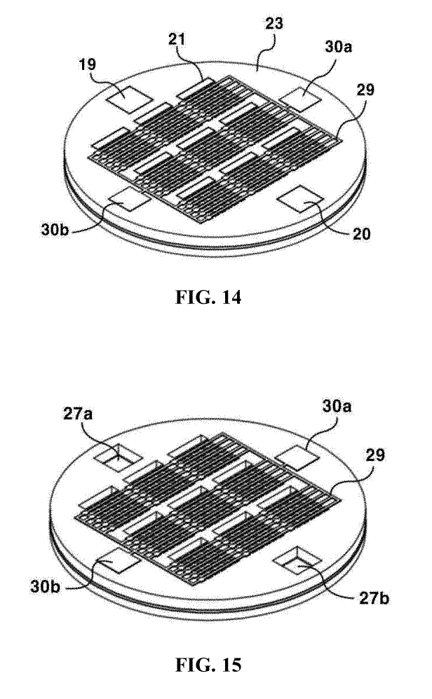

FIG. 14 is a view showing an example of forming a second electrode 29 and second poling electrodes 30a and 30b.

It may be confirmed that a plurality of second electrode lines 29 is formed on the piezoelectric material, and these electrodes are connected to the second poling electrodes 30a and 30b formed on the insulation layer 23.

The second electrode 29 and the second poling electrodes are formed of the same metal layer through the same process. Various materials may be used as the material of these electrodes, like the first electrode described above.

The second electrode 29 is formed to cross the first electrode 26 in a perpendicular direction.

The first electrode 26 may be a lower electrode, and the second electrode 29 may be an upper electrode. In the same manner, the first poling electrode 27 may be a lower poling electrode, and the second poling electrode 30 may be an upper poling electrode.

If formation of the second electrode is completed, the semiconductor material of the first area 19, the second area 20 and the third area 21 is removed so that the first poling electrode 27 and the first electrode 26 formed on the bottom may be exposed (step S17). A dry etching process (DRIE) may be used as a method of removing the semiconductor material.

FIG. 15 is a view showing a state of removing the first area 19, the second area 20 and the third area 21. If the first area 19, the second area 20 and the third area 21 are removed like this, the first electrode formed on the bottom is exposed, and thus a wire for applying voltage can be connected without inverting the substrate. That is, since the lower electrode 26, as well as the upper electrode 29, is exposed toward the top, a work of connecting wires can be performed more easily.

If the first electrode 26 and the first poling electrode 27 are exposed, the poling process is performed by applying voltage to the first poling electrode 27 and the second poling electrode 30 (step S18).

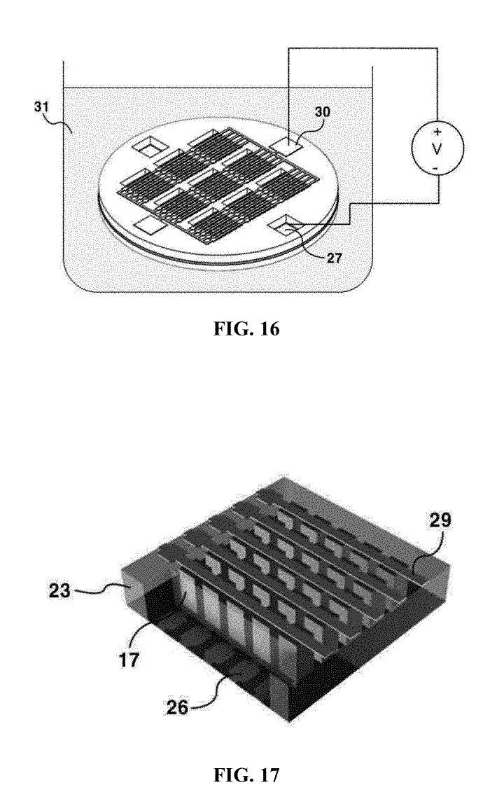

FIG. 16 is a view showing the configuration of applying a poling voltage.

Poling treatment is activating a piezoelectric material by applying high voltage to the piezoelectric material. It is also referred to as a polarization process. If a high voltage is applied to the piezoelectric material, dipoles are arranged in a predetermined direction, and this process is referred to as poling. The dipole refers to arranging two charges having the same size and opposite symbols side by side.

As shown in FIG. 16, a voltage is applied to the first poling electrode 27 and the second poling electrode 30, and since the first poling electrode 27, i.e., the lower electrode, is exposed toward the top, poling voltage also can be applied with ease. When the poling voltage is applied, the poling process may be progressed by dipping the substrate in a silicon oil 31.

At this point, since the first electrode 26 is connected to the first poling electrode 27 and the second electrode 29 is connected to the second poling electrode 30, although voltage is applied only to the first poling electrode and the second poling electrode 30, the voltage may be applied to all the piezoelectric rods 17.

If the poling process is completed, the piezoelectric rod 17 arrays are separated through a dicing process (step S19). Although the piezoelectric rods are separated through the dicing process, an unnecessary dummy substrate 28 is attached to each piezoelectric rod. Since the dummy substrate 28 is bonded using an adhesive material, it can be easily removed if a heat higher than a predetermined temperature is applied.

FIG. 17 is a view showing a piezoelectric sensor completed after a dicing process.

Referring to FIG. 17, it may be confirmed that the top of the lower electrode 26 is open and exposed to the outside, and the piezoelectric material 17 is separated by the insulation material 23. That is, the piezoelectric sensor includes the lower electrode 26, the piezoelectric material 17 of a pillar shape formed on the lower electrode, and the upper electrode 29 arranged to cross the lower electrode formed on the piezoelectric material, and the outer portion of the lower substrate is exposed without forming the piezoelectric material.

An ultrasonic piezoelectric sensor can be manufactured through the process as described above, and since both the first electrode and the second electrode are exposed in the same direction in the piezoelectric sensor manufactured in the method as described above, a wire bonding work is much easier than a conventional work.

Of course, although there is a step between the first electrode and the second electrode to some extent as shown in FIG. 17, since the step is ignorable in reality, it does not make a problem in doing a wiring work.

According to the present invention, since the top of the lower electrode of the piezoelectric sensor is open, both the upper electrode and the lower electrode of the piezoelectric sensor may be exposed on the same surface. Therefore, voltage can be applied more easily, and the manufacturing process can be reduced.

In addition, according to the present invention, both the upper poling electrode and the lower poling electrode may be exposed on the same surface. Therefore, a poling work can be performed more easily.

Although the preferred embodiments and application examples of the present invention have been described with reference to the drawings, the present invention is not limited to the specific embodiments and application examples described above. It is apparent that diverse modified embodiments can be made by those skilled in the art without departing from the scope and spirit of the present invention, and the modified embodiments should not be understood to be distinguished from the spirits and prospects of the present invention.

What is claimed is:

1. A piezoelectric sensor manufacturing method comprising the steps of:
forming a mold in a form of a sensor array pattern including a plurality of grooves by etching a semiconductor substrate;
injecting and sintering a piezoelectric material in the grooves;
forming piezoelectric rods in a form of a sensor array pattern by etching the semiconductor substrate to protrude the piezoelectric material, so that a first area at one side of the pattern protrudes;
forming an insulation layer by filling an insulation material in the semiconductor substrate;
flattening the insulation layer until the piezoelectric material is exposed;
forming a first electrode on a first surface of the piezoelectric material and the insulation layer;
bonding a dummy substrate on the semiconductor substrate on which the first electrode is formed;
flattening a second surface of the semiconductor substrate until the piezoelectric material is exposed;
forming a second electrode on the second surface of the piezoelectric material; and
exposing the first electrode by etching the first area.

2. The method according to claim 1, wherein the step of forming piezoelectric rods in the form of a sensor array pattern by etching the semiconductor substrate to protrude the piezoelectric material so that the first area on one side of the pattern protrudes,
etches the semiconductor substrate to further protrude a second area and a third area in predetermined areas of the semiconductor substrate, and
the step of exposing the first electrode by etching the first area further etches the second area and the third area.

3. The method according to claim 1, wherein the step of forming a first electrode includes the steps of:
depositing a metal layer on the piezoelectric rods;
applying photoresist on the metal layer;
removing part of the photoresist by exposing to light according to a mask pattern;
etching the metal layer of the part from which the photoresist is removed; and
removing remaining photoresist after etching the metal layer.

4. The method according to claim 2, wherein the step of forming a first electrode includes the step of forming a first poling electrode in the second area and the third area by depositing a metal layer in the second area and the third area.

5. The method according to claim 4, wherein the first electrode is connected to the first poling electrode in one piece.

6. The method according to claim 2, wherein the step of forming a second electrode includes the step of forming a second poling electrode in a predetermined area of a second surface of the insulation layer.

7. The method according to claim 6, wherein the second electrode is a metal layer the same as that of the second poling electrode.

8. The method according to claim 7, further comprising a poling step of activating the piezoelectric material by applying poling voltage to the first electrode and the second electrode.

9. The method according to claim 1, wherein the second electrode is formed to cross the first electrode in a perpendicular direction.

10. The method according to claim 1, wherein the step of forming a second electrode includes the steps of:
depositing a metal layer on the piezoelectric rods;
applying photoresist on the metal layer;
removing part of the photoresist by exposing to light according to a mask pattern;
etching the metal layer of the part from which the photoresist is removed; and
removing remaining photoresist after etching the metal layer.

11. The method according to claim 1, wherein the step of forming a mold includes the steps of:
forming a pattern for forming a sensor array on a first surface of the semiconductor substrate through a photolithography process;
removing the photoresist formed on the semiconductor substrate and depositing an insulation layer; and
forming the grooves at regular intervals on the semiconductor substrate by etching the area from which the photoresist is removed.

12. The method according to claim 1, wherein in the sintering step, the piezoelectric material is sintered at a low temperature for a first period and sintered at a high temperature for a second period.

13. The method according to claim 12, wherein the low temperature is 450 to 550° C.

14. The method according to claim 12, wherein the high temperature is 1050 to 1300° C.

15. A piezoelectric sensor comprising:
a lower electrode;
a piezoelectric material of a pillar shape formed on the lower electrode;
an upper electrode arranged to cross the lower electrode formed on the piezoelectric material, wherein
an outer portion of the lower substrate is exposed toward a top without forming the piezoelectric material.
